(19) United States
(12) Patent Application Publication
(10) Pub. No.: US 2026/0343738 A1
(43) Pub. Date: Oct. 29, 2026

(54) LAMINATED SUBSTRATE

(71) Applicant: Murata Manufacturing Co., Ltd., Nagaokakyo-shi (JP)

(72) Inventors: Michiharu NISHIMURA, Nagaokakyo-shi (JP); Yasuyuki Sekimoto, Nagaokakyo-shi (JP); Sunao Fukutake, Nagaokakyo-shi (JP)

(21) Appl. No.: 19/703,274

(22) Filed: Jun. 10, 2026

Related U.S. Application Data
(63) Continuation of application No. PCT/JP2024/041729, filed on Nov. 26, 2024.

(30) Foreign Application Priority Data
Dec. 22, 2023 (JP) 2023-216733

(51) Int. Cl. H05K 1/03; H05K 1/02

(52) U.S. Cl. CPC H05K 1/036; H05K 1/0298; H05K 2201/0129; H05K 2201/068

(57) ABSTRACT

A multilayer substrate including: a first resin layer having first and second main surfaces opposing each other in a thickness direction; a second resin layer having third and fourth main surfaces opposing each other in the thickness direction, the fourth main surface facing the first main surface; and a first conductor layer between the first resin layer and the second resin layer and in contact with the first main surface and the fourth main surface, wherein the first resin layer and the second resin layer each include a first resin material including a first thermoplastic resin and a second resin material including a second thermoplastic resin and dispersed in the first resin material, wherein, at an interface between the first resin layer and the first conductor layer in a first cross-section taken along the thickness direction, a proportion of presence of the second resin material is 40% to 70%.

### CROSS REFERENCE TO RELATED APPLICATIONS

The present application is a continuation of International application No. PCT/JP2024/041729, filed Nov. 26, 2024, which claims priority to Japanese Patent Application No. 2023-216733, filed Dec. 22, 2023, the entire contents of each of which are incorporated herein by reference.

### TECHNICAL FIELD

The present disclosure relates to a multilayer substrate.

### BACKGROUND ART

Patent Literature 1 discloses a stacked body including: a thermoplastic first resin layer; a conductor pattern provided on one principal surface of the first resin layer; and a thermoplastic second resin layer, wherein the first resin layer is softer than the second resin layer; the first resin layer has a lower dielectric constant than the second resin layer; and the conductor pattern includes a portion in contact with the first resin layer along a layer direction of the first resin layer and a portion in contact with the first resin layer along a stacking direction of the first resin layer, the second resin layer, and the conductor pattern.
Patent Literature 1: WO 2020/071473

### SUMMARY OF THE DISCLOSURE

In the stacked body described in Patent Literature 1, as shown in FIG. 1 and the like of Patent Literature 1, the first resin layers mainly composed of a fluorine resin that is likely to undergo dimensional change during heating or the like (for example, that has a large coefficient of thermal expansion) are provided in a layered form. Therefore, the stacked body described in Patent Literature 1 has a configuration in which the first resin layers are likely to undergo dimensional change. Furthermore, in the stacked body described in Patent Literature 1, the conductor patterns are considered to be less likely to undergo dimensional change than the first resin layers (for example, have a smaller coefficient of thermal expansion). Accordingly, in the stacked body described in Patent Literature 1, the tendency of the first resin layers to undergo dimensional change, and the differences in dimensional change between the first resin layers and the conductor patterns may cause undesirable changes such as reduced adhesion between the first resin layers and the conductor patterns and warpage of the stacked body.

The present disclosure has been made to solve the above problems and aims to provide a multilayer substrate having excellent adhesion between a resin layer and a conductor layer while suppressing warpage.

The multilayer substrate of the present disclosure includes: a first resin layer having a first main surface and a second main surface opposing each other in a thickness direction; a second resin layer having a third main surface and a fourth main surface opposing each other in the thickness direction, the fourth main surface facing the first main surface; and a first conductor layer between the first resin layer and the second resin layer and in contact with the first main surface and the fourth main surface, wherein the first resin layer and the second resin layer each include a first resin material comprising a first thermoplastic resin and a second resin material comprising a second thermoplastic resin and dispersed in the first resin material, wherein Tm1>Tm2, where Tm1 is a melting point of the first resin material, and Tm2 is a melting point of the second resin material, wherein, in a surface direction perpendicular to the thickness direction, |CTE3−CTE2|>|CTE3−CTE1|, where CTE1 is a coefficient of thermal expansion of the first resin material, CTE2 is a coefficient of thermal expansion of the second resin material, and CTE3 is a coefficient of thermal expansion of the first conductor layer, and wherein, at an interface between the first resin layer and the first conductor layer in a first cross-section taken along the thickness direction, a proportion of presence of the second resin material is 40% to 70%.

The present disclosure can provide a multilayer substrate having excellent adhesion between a resin layer and a conductor layer while suppressing warpage.

### BRIEF DESCRIPTION OF THE DRAWINGS

FIG. 1 is a schematic cross-sectional view of an example of a multilayer substrate of Embodiment 1 of the present disclosure, in a first cross-section taken along the thickness direction.

FIG. 2 is a schematic cross-sectional view of the example of the multilayer substrate of Embodiment 1 of the present disclosure, in a second cross-section perpendicular to the first cross-section and taken along the thickness direction.

FIG. 3 is a partially enlarged schematic cross-sectional view of the multilayer substrate shown in FIG. 1, for explaining a method of determining the proportion of presence of a second resin material at an interface between a first resin layer and a first conductor layer.

FIG. 4 is a schematic cross-sectional view illustrating a step of producing a conductor layer-attached resin sheet in an example of a method of producing a multilayer substrate of Embodiment 1 of the present disclosure.

FIG. 5 is a schematic cross-sectional view illustrating a step of producing another conductor layer-attached resin sheet in the example of the method of producing a multilayer substrate of Embodiment 1 of the present disclosure.

FIG. 6 is a schematic cross-sectional view illustrating a step of stacking conductor layer-attached resin sheets in the example of the method of producing a multilayer substrate of Embodiment 1 of the present disclosure.

FIG. 7 is an example of an enlarged cross-sectional image of the multilayer substrate of Embodiment 1 of the present disclosure.

FIG. 8 is a cross-sectional view for explaining methods of determining an average thickness, an average aspect ratio, and an average inclination of the second resin material.

FIG. 9 is an enlarged schematic cross-sectional view of another example of the multilayer substrate of Embodiment 1 of the present disclosure, in a second cross-section.

FIG. 10 is an enlarged schematic cross-sectional view of still another example of the multilayer substrate of Embodiment 1 of the present disclosure, in a second cross-section.

FIG. 11 is a schematic cross-sectional view of an example of a multilayer substrate of Embodiment 2 of the present disclosure, in a second cross-section.

FIG. 12 is a schematic cross-sectional view of an example of a multilayer substrate of Embodiment 3 of the present disclosure, in a second cross-section.

FIG. 13 is a schematic cross-sectional view of an example of a multilayer substrate of Embodiment 4 of the present disclosure, in a second cross-section.

FIG. 14 is a schematic cross-sectional view of an example of a multilayer substrate of Embodiment 5 of the present disclosure, in a first cross-section.

FIG. 15 is a schematic cross-sectional view of an example of a multilayer substrate of Embodiment 6 of the present disclosure, in a first cross-section.

### DESCRIPTION OF THE PREFERRED EMBODIMENTS

Hereinafter, the multilayer substrate of the present disclosure will be described. The present disclosure is not limited to the following preferred embodiments, and may be suitably modified without departing from the gist of the present disclosure. Combinations of two or more preferred features described in the following preferred embodiments are also within the scope of the present disclosure.

The following preferred embodiments are examples, and features of different preferred embodiments can be partially exchanged or combined with each other. In the second preferred embodiment and subsequent preferred embodiments, a description of features common to the first preferred embodiment is omitted, and only different points are described. In particular, similar advantageous effects by similar features are not mentioned in each preferred embodiment.

In the following description, when no distinction is made among the embodiments, the multilayer substrates of the embodiments are simply referred to as “the multilayer substrate of the present disclosure.”

The drawings shown below are schematic diagrams, and their dimensions and aspect ratio scales may differ from those of the actual products.

Unless otherwise specified herein, terms indicating relationships between elements (e.g., “parallel,” “perpendicular”) and terms indicating the shapes of elements are not limited to strictly literal embodiments, but also encompass substantially equivalent ranges, including, for example, differences of several percent.

The multilayer substrate of the present disclosure includes: a first resin layer having a first main surface and a second main surface opposing each other in a thickness direction; a second resin layer having a third main surface and a fourth main surface opposing each other in the thickness direction, the fourth main surface facing the first main surface; and a first conductor layer between the first resin layer and the second resin layer and in contact with the first main surface and the fourth main surface, wherein the first resin layer and the second resin layer each include a first resin material comprising a first thermoplastic resin and a second resin material comprising a second thermoplastic resin and dispersed in the first resin material, wherein Tm1>Tm2, where Tm1 is a melting point of the first resin material, and Tm2 is a melting point of the second resin material, wherein, in a surface direction perpendicular to the thickness direction, |CTE3−CTE2|>|CTE3−CTE1|, where CTE1 is a coefficient of thermal expansion of the first resin material, CTE2 is a coefficient of thermal expansion of the second resin material, and CTE3 is a coefficient of thermal expansion of the first conductor layer, and wherein, at an interface between the first resin layer and the first conductor layer in a first cross-section taken along the thickness direction, a proportion of presence of the second resin material is 40% to 70%.

### Embodiment 1

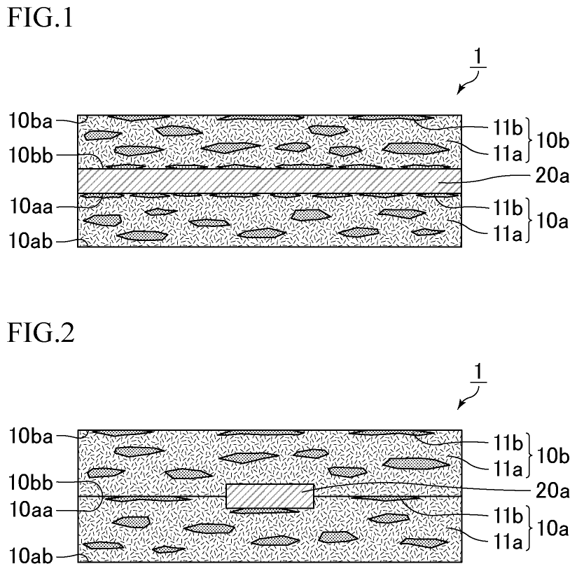

FIG. 1 is a schematic cross-sectional view of an example of a multilayer substrate of Embodiment 1 of the present disclosure, in a first cross-section taken along the thickness direction. FIG. 2 is a schematic cross-sectional view of the example of the multilayer substrate of Embodiment 1 of the present disclosure, in a second cross-section perpendicular to the first cross-section taken along the thickness direction.

A multilayer substrate 1 shown in FIG. 1 and FIG. 2 includes a first resin layer 10a, a second resin layer 10b, and a first conductor layer 20a.

The first cross-section of the multilayer substrate 1 shown in FIG. 1 refers to, for example, a cross-section of the multilayer substrate 1 taken along the thickness direction of the multilayer substrate 1 (in FIG. 1, the upper-lower direction) and the extension direction of the first conductor layer 20a (in FIG. 1, the left-right direction) when the first conductor layer 20a extends in a specific direction. The second cross-section of the multilayer substrate 1 shown in FIG. 2 refers to, for example, a cross-section of the multilayer substrate 1 taken along the thickness direction of the multilayer substrate 1 (in FIG. 2, the upper-lower direction) and a direction perpendicular to the extension direction of the first conductor layer 20a (in FIG. 2, the left-right direction) when the first conductor layer 20a extends in a specific direction.

The first resin layer 10a has a first main surface 10aa and a second main surface 10ab opposing each other in the thickness direction.

The second resin layer 10b has a third main surface 10ba and a fourth main surface 10bb opposing each other in the thickness direction.

The fourth main surface 10bb of the second resin layer 10b faces the first main surface 10aa of the first resin layer 10a. In the example shown in FIG. 2, the fourth main surface 10bb of the second resin layer 10b is in contact with the first main surface 10aa of the first resin layer 10a at portions other than portions in contact with the first conductor layer 20a.

The first resin layer 10a and the second resin layer 10b each include a first resin material 11a and a second resin material 11b.

The first resin material 11a is made of a thermoplastic resin.

Examples of the thermoplastic resin constituting the first resin material 11a include liquid crystal polymers (LCP), thermoplastic polyimide (TPI), polyphenylene sulfide (PPS), and polyether ether ketone (PEEK).

The first resin material 11a preferably includes a liquid crystal polymer. Since liquid crystal polymers have a low relative permittivity among thermoplastic resins, the first resin material 11a including a liquid crystal polymer is likely to improve dielectric characteristics in a high-frequency range of the multilayer substrate 1. In addition, since liquid crystal polymers have low hygroscopicity, the first resin material 11a including a liquid crystal polymer is less likely to cause changes in dielectric characteristics due to moisture absorption in the multilayer substrate 1.

When the first resin material 11a includes a liquid crystal polymer, the liquid crystal polymer constituting the first resin material 11a preferably includes a copolymer of p-hydroxybenzoic acid (HBA) and 6-hydroxy-2-naphthoic acid (HNA).

The copolymer of p-hydroxybenzoic acid and 6-hydroxy-2-naphthoic acid is generally referred to as a type II wholly aromatic polyester (also referred to as a type 1.5 wholly aromatic polyester). Type II wholly aromatic polyesters are less likely to undergo hydrolysis than type III partially aromatic polyesters, and are therefore more preferable as a constituent material of the multilayer substrate 1. In addition, type II wholly aromatic polyesters contribute to a reduction in electrical energy loss in the first resin layer 10a in the multilayer substrate 1 owing to their low dielectric loss tangent derived from a naphthalene ring structure.

When the first resin material 11a includes a liquid crystal polymer, the liquid crystal polymer constituting the first resin material 11a may further include, in addition to the type II wholly aromatic polyester, a type I wholly aromatic polyester, a type III partially aromatic polyester, or both a type I wholly aromatic polyester and a type III partially aromatic polyester.

The structure (type) of each monomer constituting the liquid crystal polymer can be analyzed by reactive pyrolysis gas chromatography-mass spectrometry (reactive pyrolysis GC-MS).

The second resin material 11b is made of a thermoplastic resin.

Examples of the thermoplastic resin constituting the second resin material 11b include perfluoroalkoxyalkane (PFA) (fluorine-containing resin), thermoplastic polyimide (TPI), polyphenylene sulfide (PPS), polyether ether ketone (PEEK), polyphenylene ether (PPE), polymethyl pentene (PMP), crosslinked polyethylene (XLPE), and polynorbornene (PNB).

The second resin material 11b preferably includes perfluoroalkoxyalkane, thermoplastic polyimide, polyphenylene sulfide, polyether ether ketone, polyphenylene ether, polymethyl pentene, crosslinked polyethylene, or polynorbornene.

The second resin material 11b more preferably includes perfluoroalkoxyalkane, polymethyl pentene, or polynorbornene.

Since perfluoroalkoxyalkane has a lower relative permittivity than liquid crystal polymers, the second resin material 11b including perfluoroalkoxyalkane is more likely to improve dielectric characteristics in a high-frequency range of the multilayer substrate 1. In addition, since perfluoroalkoxyalkane has low hygroscopicity similar to liquid crystal polymers, the second resin material 11b including perfluoroalkoxyalkane is less likely to cause changes in dielectric characteristics due to moisture absorption in the multilayer substrate 1. Furthermore, since perfluoroalkoxyalkane has a high heat-resistant temperature of 260 °C or higher, the second resin material 11b including perfluoroalkoxyalkane renders, for example, the multilayer substrate 1 less prone to damage when the multilayer substrate 1 is incorporated into an electronic device by reflow soldering.

Since polymethyl pentene has low relative permittivity and a low dielectric loss tangent similar to perfluoroalkoxyalkane, the second resin material 11b including polymethyl pentene is likely to improve dielectric characteristics in a high-frequency range of the multilayer substrate 1. In addition, since polymethyl pentene has low hygroscopicity similar to perfluoroalkoxyalkane, the second resin material 11b including polymethyl pentene is less likely to cause changes in dielectric characteristics due to moisture absorption in the multilayer substrate 1. Furthermore, since polymethyl pentene has a smaller coefficient of thermal expansion than perfluoroalkoxyalkane, the second resin material 11b including polymethyl pentene renders the multilayer substrate 1 less prone to dimensional changes. Moreover, since polymethyl pentene has higher tensile strength (for example, tensile elongation at break) than perfluoroalkoxyalkane, the second resin material 11b including polymethyl pentene further increases the strength of the multilayer substrate 1.

Since polynorbornene has low relative permittivity and a low dielectric loss tangent similar to perfluoroalkoxyalkane, the second resin material 11b including polynorbornene is likely to improve dielectric characteristics in a high-frequency range of the multilayer substrate 1. In addition, since polynorbornene has low hygroscopicity similar to perfluoroalkoxyalkane, the second resin material 11b including polynorbornene is less likely to cause changes in dielectric characteristics due to moisture absorption in the multilayer substrate 1. Furthermore, since polynorbornene has a smaller coefficient of thermal expansion than perfluoroalkoxyalkane, the second resin material 11b including polynorbornene renders the multilayer substrate 1 less prone to dimensional changes. Moreover, since polynorbornene has a higher tensile modulus than perfluoroalkoxyalkane, the second resin material 11b including polynorbornene further increases the bending rigidity of the multilayer substrate 1.

The type of resin material present in a resin layer is identified as follows. First, the multilayer substrate is polished to expose a cross-section along the thickness direction (for example, a first cross-section). Then, the exposed cross-section of the multilayer substrate is analyzed using a microscopic Fourier transform infrared spectrophotometer (microscopic FT-IR) to identify the type of resin material present in the resin layer.

The second resin material 11b is dispersed in the first resin material 11a. As a result, the second resin material 11b functions as a filler in the first resin material 11a and is likely to be constrained by the first resin material 11a.

The first resin layer 10a and the second resin layer 10b may each further include, in addition to the first resin material 11a and the second resin material 11b, other materials (for example, resin materials). In this case, in each of the first resin layer 10a and the second resin layer 10b, for example, the proportion of the first resin material 11a is the largest, and the proportion of the second resin material 11b is the next largest. The proportion of a resin material is determined, for example, by measuring the area proportion of the resin material in a cross-sectional image of the resin layer along the thickness direction (for example, an image of the first cross-section) using image analysis software.

The first resin layer 10a and the second resin layer 10b may have the same thickness or may have different thicknesses.

The first conductor layer 20a is located between the first resin layer 10a and the second resin layer 10b and is in contact with the first main surface 10aa of the first resin layer 10a and the fourth main surface 10bb of the second resin layer 10b. In this manner, no other layer such as an adhesive layer is provided between the first resin layer 10a and the first conductor layer 20a and between the second resin layer 10b and the first conductor layer 20a.

The first conductor layer 20a preferably extends across the interface between the first resin layer 10a and the second resin layer 10b. Accordingly, the interface between the first resin layer 10a and the first conductor layer 20a and the interface between the second resin layer 10b and the first conductor layer 20a are shifted in the thickness direction relative to the interface between the first resin layer 10a and the second resin layer 10b, thereby suppressing peeling at the interface between the first resin layer 10a and the first conductor layer 20a, and peeling at the interface between the second resin layer 10b and the first conductor layer 20a.

Although the interface between the first resin layer 10a and the second resin layer 10b is shown in FIG. 2, this interface may not be clearly visible in practice. When the interface between the first resin layer 10a and the second resin layer 10b is not clearly visible, in a second cross-section along the thickness direction as shown in FIG. 2, a plane that passes through the center of a cross-section of the first conductor layer 20a in the thickness direction and extends along a surface direction perpendicular to the thickness direction (in FIG. 2, the left-right direction) is regarded as the interface between the first resin layer 10a and the second resin layer 10b.

The first conductor layer 20a may be in a planar form extending over the entire first main surface 10aa of the first resin layer 10a or the entire fourth main surface 10bb of the second resin layer 10b, or may be in a patterned form such as wiring on a part of the first main surface 10aa of the first resin layer 10a or a part of the fourth main surface 10bb of the second resin layer 10b.

Examples of constituent materials of the first conductor layer 20a include copper, silver, aluminum, stainless steel, nickel, gold, and alloys containing at least one of these metals.

The first conductor layer 20a includes, for example, a metal foil, and among metal foils, a copper foil is preferred. In this case, a metal other than copper may be present on a surface of the copper foil.

The thickness of the first conductor layer 20a is preferably 1 μm to 35 μm, more preferably 6 μm to 18 μm.

In the multilayer substrate 1, Tm1>Tm2, where Tm1 is the melting point of the first resin material 11a and Tm2 is the melting point of the second resin material 11b.

The melting point of a resin material present in a resin layer is determined as follows. First, a conductor layer is removed from a multilayer substrate by a method such as peeling or etching to isolate the resin layer. Then, a target resin material (for example, a first resin material or a second resin material) is separated from the resin layer by a method such as scraping. Thereafter, the melting point of the target resin material is measured using a differential scanning calorimeter (DSC). In the above-described method, when the melting point of the target resin material cannot be clearly measured and when the target resin material is an amorphous resin material, a glass transition temperature (Tg) may be used instead.

In the multilayer substrate 1, in a surface direction perpendicular to the thickness direction, |CTE3−CTE2|>|CTE3−CTE1|, where CTE1 is the coefficient of thermal expansion of the first resin material 11a, CTE2 is the coefficient of thermal expansion of the second resin material 11b, and CTE3 is the coefficient of thermal expansion of the first conductor layer 20a.

In the multilayer substrate 1, preferably, CTE1<CTE2. In this case, a difference between CTE1 and CTE2 is preferably 20 ppm/°C to 120 ppm/°C.

In the multilayer substrate 1, preferably, CTE1<CTE3. In this case, a difference between CTE1 and CTE3 is preferably 2 ppm/°C to 10 ppm/°C.

In the multilayer substrate 1, preferably, CTE2>CTE3. In this case, a difference between CTE2 and CTE3 is preferably 30 ppm/°C to 110 ppm/°C.

When the first conductor layer 20a includes a copper foil, CTE3 is approximately 16 ppm/°C.

A coefficient of thermal expansion of a resin material present in a resin layer in a surface direction is determined as follows. First, a conductor layer and the like are removed from a multilayer substrate by a method such as peeling or etching to isolate a target resin layer (for example, a first resin layer). Then, a coefficient of thermal expansion of the target resin layer in the surface direction is measured by a thermomechanical analysis (TMA) method. In this measurement, a coefficient of thermal expansion of a target resin layer sample in the surface direction is determined, for example, by cutting out a resin layer sample having a length of 20 mm and a width of 4 mm; subjecting the resin layer sample to heating and then cooling under measurement conditions including a measurement mode of a tensile mode, a distance between chucks of 10 mm, a load of 5 g, a heating rate of 40 °C/min, and a cooling rate of 10 °C/min; and measuring an amount of change in the distance between chucks in a temperature range from 100 °C to 50 °C in the cooling process. Next, an elastic modulus of the target resin layer sample is measured by a tensile mode of dynamic mechanical analysis (DMA). Meanwhile, by the method described above, types of resin materials present in the target resin layer sample are identified in a cross-section of the target resin layer sample along a thickness direction (for example, a first cross-section). Then, for example, an area proportion of a target resin material (for example, a first resin material or a second resin material) in the cross-section of the target resin layer sample is measured using image analysis software. In addition, an elastic modulus of the target resin material in the cross-section of the target resin layer sample is measured in an elastic modulus measurement mode of a scanning probe microscope (SPM). Based on the measured data obtained as described above, a coefficient of thermal expansion of the target resin material in the surface direction is calculated from the coefficient of thermal expansion of the target resin layer sample in the surface direction according to the area proportion and elastic modulus of the target resin material. For example, when a sample of the first resin layer 10a including the first resin material 11a and the second resin material 11b is used, the following equation (A) holds as a stress-neutral relationship:

CTE1×E1×V1+CTE2×E2×V2=CTEt×Et×(V1+V2) (A)

wherein CTE1 is a coefficient of thermal expansion of the first resin material 11a in the surface direction (unit: ppm/°C), CTE2 is a coefficient of thermal expansion of the second resin material 11b in the surface direction (unit: ppm/°C), CTEt is a coefficient of thermal expansion of the sample of the first resin layer 10a in the surface direction (unit: ppm/°C), E1 is an elastic modulus of the first resin material 11a (unit: GPa), E2 is an elastic modulus of the second resin material 11b (unit: GPa), Et is an elastic modulus of the sample of the first resin layer 10a (unit: GPa), V1 is an area proportion of the first resin material 11a (unit: %), and V2 is an area proportion of the second resin material 11b (unit: %).

Here, CTEt, E1, E2, Et, V1, and V2 are measured by the methods described above. Furthermore, CTE2 is measured by the following method. First, a sample of the first resin layer 10a is subjected to a strong alkali treatment to remove the first resin material 11a from the sample of the first resin layer 10a. Then, the second resin material 11b (in the form of a plurality of irregular lump-shaped bodies) separated from the sample of the first resin layer 10a is subjected to hot press processing at a temperature equal to or higher than a temperature that is 20 °C lower than the melting point of the second resin material 11b and a temperature equal to or lower than the melting point of the second resin material 11b (i.e., a temperature of (Tm2−20) or higher and Tm2 or lower) with a pressure set to, for example, 2 MPa to 3 MPa, thereby producing a resin sheet made of the second resin material 11b with a thickness of 50 μm to 500 μm. Thereafter, a coefficient of thermal expansion CTE2 of the resin sheet made of the second resin material 11b in the surface direction is measured by a thermomechanical analysis method. Using CTE2, CTEt, E1, E2, Et, V1, and V2 obtained as described above, CTE1 is calculated from the following equation (B) obtained by modifying equation (A).

CTE1=[CTEt×Et×(V1+V2)−CTE2×E2×V2]/[E1×V1] (B)

A coefficient of thermal expansion of a conductor layer in the surface direction is determined as follows. First, a target conductor layer is separated from a multilayer substrate by a method such as peeling. Then, a coefficient of thermal expansion of the target conductor layer in the surface direction is measured by a thermomechanical analysis method. In measuring the coefficient of thermal expansion of the conductor layer in the surface direction, for example, measurement conditions similar to those used when measuring a coefficient of thermal expansion of a resin layer in the surface direction are employed.

In the multilayer substrate 1, at an interface between the first resin layer 10a and the first conductor layer 20a in a first cross-section taken along the thickness direction as shown in FIG. 1, the proportion of presence of the second resin material 11b (hereinafter, also referred to as “the proportion of presence of the second resin material 11b at an interface between the first resin layer 10a and the first conductor layer 20a”) is 40% to 70%.

The proportion of presence of the second resin material 11b at the interface between the first resin layer 10a and the first conductor layer 20a is determined as follows.

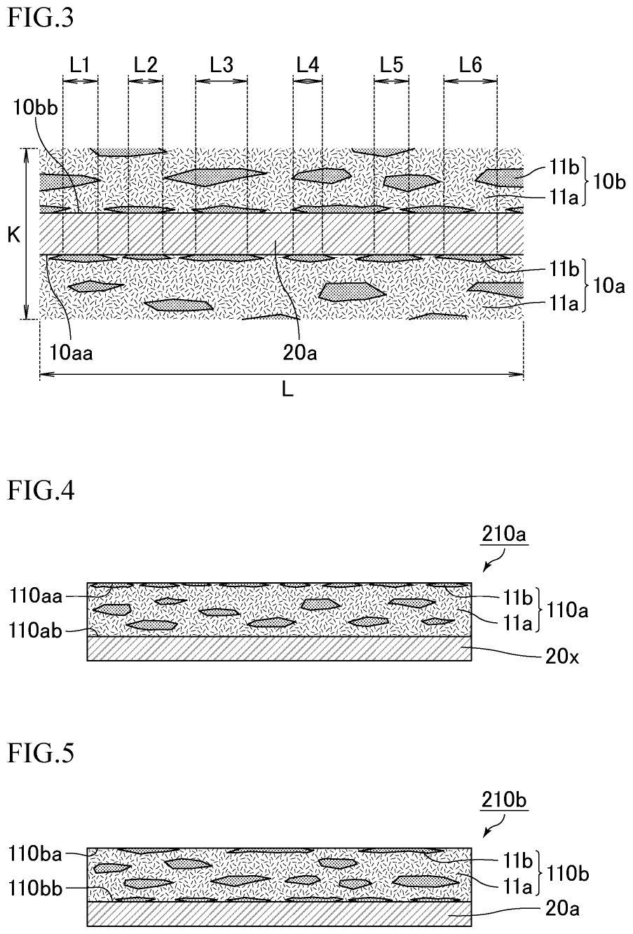

FIG. 3 is a partially enlarged schematic cross-sectional view of the multilayer substrate shown in FIG. 1, for explaining a method of determining the proportion of presence of a second resin material at an interface between a first resin layer and a first conductor layer.

First, the multilayer substrate 1 is polished to expose a first cross-section along the thickness direction as shown in FIG. 1. Next, the first cross-section of the multilayer substrate 1 is imaged at an imaging magnification of 500 times using a scanning electron microscope (SEM). At this time, as shown in FIG. 3, the imaging range includes at least a part of the interface between the first resin layer 10a and the first conductor layer 20a and has a dimension K in the thickness direction of 100 μm and a dimension L in the surface direction of 200 μm. The interface between the first resin layer 10a and the first conductor layer 20a can be confirmed using the scanning electron microscope. Then, in the obtained cross-sectional image of the multilayer substrate 1, for each domain of the second resin material 11b present at the interface between the first resin layer 10a and the first conductor layer 20a, a dimension in the surface direction of a portion (an exposed portion) in contact with the interface between the first resin layer 10a and the first conductor layer 20a (the main surface of the first conductor layer 20a adjacent to the first resin layer 10a) is determined. In the example shown in FIG. 3, six domains of the second resin material 11b are present at the interface between the first resin layer 10a and the first conductor layer 20a, and for each of these six domains of the second resin material 11b, dimensions L1, L2, L3, L4, L5, and L6 in the surface direction of portions (the exposed portions) in contact with the interface between the first resin layer 10a and the first conductor layer 20a (the main surface of the first conductor layer 20a adjacent to the first resin layer 10a) are determined. Thereafter, 100×(a sum of dimensions in the surface direction of portions of the second resin material 11b that are in contact with the interface between the first resin layer 10a and the first conductor layer 20a (the main surface of the first conductor layer 20a adjacent to the first resin layer 10a))/(a dimension L in the surface direction of the imaging range), which is, in the example shown in FIG. 3, 100×(L1+L2+L3+L4+L5+L6)/L, is calculated. The resulting value is defined as the proportion of presence of the second resin material 11b at the interface between the first resin layer 10a and the first conductor layer 20a (unit: %).

The multilayer substrate 1, in which Tm1>Tm2, |CTE3−CTE2|>|CTE3−CTE1|, and the proportion of presence of the second resin material 11b at an interface between the first resin layer 10a and the first conductor layer 20a is 40% to 70%, exhibits excellent adhesion between the first resin layer 10a and the first conductor layer 20a while suppressing warpage. Hereinafter, a mechanism by which such effects of the multilayer substrate 1 are achieved will be described with reference to an example of a method of producing the multilayer substrate 1.

The multilayer substrate 1 is produced, for example, as described below.

### <Step of Producing Conductor Layer-Attached Resin Sheet>

FIG. 4 is a schematic cross-sectional view illustrating a step of producing a conductor layer-attached resin sheet in an example of a method of producing a multilayer substrate of Embodiment 1 of the present disclosure.

First, the first resin material 11a and the second resin material 11b are blended to prepare a resin composition. At this time, for example, the first resin material 11a and the second resin material 11b are finely pulverized and then dispersed in a dispersion medium to prepare a paste-like or slurry-like resin composition. The dispersion medium may be, for example, butanediol, water, ethanol, or a mixture containing at least two of these.

Next, using the resin composition, a first resin sheet 110a including the first resin material 11a and the second resin material 11b is produced. At this time, for example, the first resin sheet 110a is produced by a method of applying the resin composition and then drying the applied resin composition (evaporating the dispersion medium), or a method of papermaking the resin composition and then drying the papermaking-formed resin composition (evaporating the dispersion medium).

Herein, a sheet is synonymous with a film, and they are not distinguished by thickness.

Next, a conductor layer-attached first resin sheet 210a as shown in FIG. 4 is produced, in which a conductor layer 20x is adjacent to a second main surface 110ab of the first resin sheet 110a having a first main surface 110aa and the second main surface 110ab opposing each other in the thickness direction. At this time, for example, the conductor layer-attached first resin sheet 210a is produced by compression-bonding the conductor layer 20x to the second main surface 110ab of the first resin sheet 110a.

In compression-bonding the conductor layer 20x to the first resin sheet 110a, for example, hot press processing is performed by pressing the stack of the first resin sheet 110a and the conductor layer 20x together in the thickness direction while heating. The temperature during the hot press processing is preferably equal to or higher than the melting point of the second resin material 11b and equal to or lower than the melting point of the first resin material 11a (i.e., Tm2 or higher and Tm1 or lower), more preferably equal to or higher than the melting point of the second resin material 11b and equal to or lower than a temperature that is 10 °C lower than the melting point of the first resin material 11a (i.e., Tm2 or higher and (Tm1−10) or lower). In this case, a temperature increase rate during the hot press processing is preferably 5 °C/min or higher, more preferably 5 °C/min or higher and 50 °C/min or lower. When hot press processing is performed, for example, under the temperature conditions described above, the second resin material 11b tends to melt and connect in the surface direction, as shown in FIG. 4, thereby forming a flat shape (layer shape) along the surface direction and being likely to be present in a flat shape at the first main surface 110aa of the first resin sheet 110a.

The conductor layer 20x may be patterned by etching after being compression-bonded to the first resin sheet 110a.

FIG. 5 is a schematic cross-sectional view illustrating a step of producing another conductor layer-attached resin sheet in the example of the method of producing a multilayer substrate of Embodiment 1 of the present disclosure.

Similar to the method of producing the conductor layer-attached first resin sheet 210a, a conductor layer-attached second resin sheet 210b as shown in FIG. 5 is produced, in which a first conductor layer 20a is adjacent to a fourth main surface 110bb of a second resin sheet 110b having a third main surface 110ba and the fourth main surface 110bb opposing each other in the thickness direction. When hot press processing is performed on the stack of the second resin sheet 110b and the first conductor layer 20a, for example, under the temperature conditions described above, the second resin material 11b tends to melt and connect in the surface direction, as shown in FIG. 5, thereby forming a flat shape (layer shape) along the surface direction and being likely to be present in a flat shape at the third main surface 110ba of the second resin sheet 110b.

### <Step of Stacking Conductor Layer-Attached Resin Sheets>

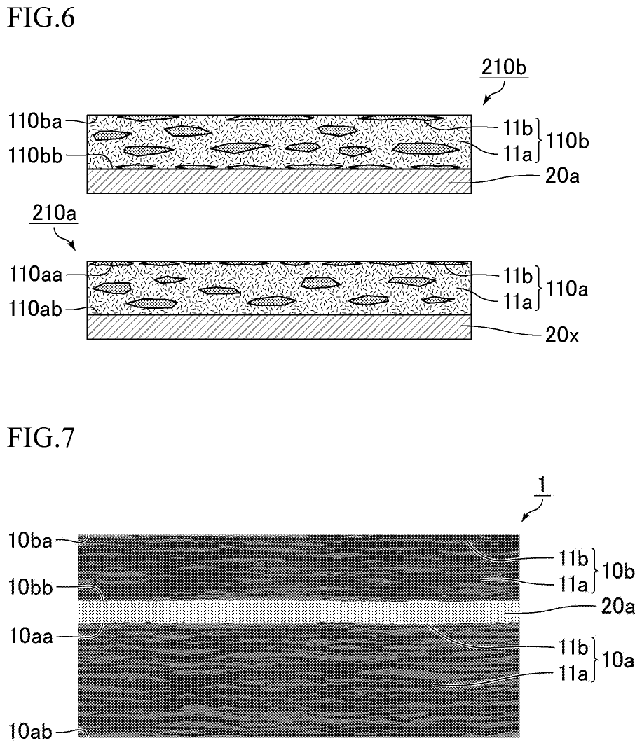

FIG. 6 is a schematic cross-sectional view illustrating a step of stacking conductor layer-attached resin sheets in the example of the method of producing a multilayer substrate of Embodiment 1 of the present disclosure.

As shown in FIG. 6, the conductor layer-attached first resin sheet 210a and the conductor layer-attached second resin sheet 210b are stacked in the thickness direction. Specifically, the conductor layer-attached first resin sheet 210a and the conductor layer-attached second resin sheet 210b are stacked in the thickness direction such that a surface on a first resin sheet 110a side of the conductor layer-attached first resin sheet 210a and a surface on a first conductor layer 20a side of the conductor layer-attached second resin sheet 210b are in contact with each other. In FIG. 6, for convenience of explanation, the conductor layer-attached resin sheets are shown in a state separated from each other.

Then, hot press processing is performed on the obtained stack by pressing the stack together in the thickness direction while heating. As a result, the conductor layer-attached first resin sheet 210a and the conductor layer-attached second resin sheet 210b are compression-bonded, and the first resin sheet 110a and the second resin sheet 110b become a first resin layer 10a and a second resin layer 10b, respectively.

The temperature during the hot press processing is preferably equal to or higher than the melting point of the second resin material 11b and equal to or lower than the melting point of the first resin material 11a (i.e., Tm2 or higher and Tm1 or lower), more preferably equal to or higher than the melting point of the second resin material 11b and equal to or lower than a temperature that is 10 °C lower than the melting point of the first resin material 11a (i.e., Tm2 or higher and (Tm1−10) or lower). In this case, a temperature increase rate during the hot press processing is preferably 5 °C/min or higher, more preferably 5 °C/min or higher and 50 °C/min or lower. When hot press processing is performed, for example, under the temperature conditions described above, as shown in FIG. 6, the second resin material 11b can be caused to be present at an interface between the first resin layer 10a and the first conductor layer 20a at a proportion of presence of 40% to 70% while maintaining a flat shape along the surface direction.

As described above, since Tm1>Tm2, in compression-bonding the conductor layer-attached first resin sheet 210a and the conductor layer-attached second resin sheet 210b, hot press processing can be performed at a temperature of Tm2 or higher and Tm1 or lower.

When hot press processing is performed at a temperature of Tm2 or higher, fluidity of the second resin material 11b present at the interface (or in the vicinity thereof) between the first resin layer 10a and the first conductor layer 20a increases, thereby reducing the distance between the second resin material 11b in the first resin layer 10a and the first conductor layer 20a. At this time, since the proportion of presence of the second resin material 11b at the interface between the first resin layer 10a and the first conductor layer 20a is 40% or more, adhesion between the second resin material 11b in the first resin layer 10a and the first conductor layer 20a is enhanced, resulting in an excellent adhesion between the first resin layer 10a and the first conductor layer 20a.

On the other hand, when hot press processing is performed at a temperature of Tm1 or lower, fluidity of the first resin material 11a does not increase, and thus aggregation of the second resin material 11b is suppressed by the first resin material 11a. As a result, the second resin material 11b can be caused to be present while maintaining a flat shape along the surface direction.

Furthermore, as described above, since |CTE3−CTE2|>|CTE3−CTE1|, hot press processing can be performed such that the coefficient of thermal expansion of the first resin material 11a in the surface direction is closer to the coefficient of thermal expansion of the first conductor layer 20a in the surface direction than the coefficient of thermal expansion of the second resin material 11b in the surface direction. In other words, hot press processing can be performed in a state in which, relative to the first conductor layer 20a, the first resin material 11a undergoes dimensional changes less readily than the second resin material 11b. At this time, since the proportion of presence of the second resin material 11b at the interface between the first resin layer 10a and the first conductor layer 20a is 70% or less, at the interface between the first resin layer 10a and the first conductor layer 20a, dimensional changes of the second resin material 11b are suppressed by the first resin material 11a that less readily undergoes dimensional changes relative to the first conductor layer 20a. As a result, the coefficient of thermal expansion of the first resin layer 10a in the surface direction including the first resin material 11a and the second resin material 11b becomes closer to the coefficient of thermal expansion of the first conductor layer 20a in the surface direction, and thus warpage caused by a difference in coefficient of thermal expansion between the first resin layer 10a and the first conductor layer 20a in the surface direction, i.e., a difference in dimensional change between the first resin layer 10a and the first conductor layer 20a, is suppressed.

Subsequently, after performing hot press processing, the conductor layer 20x is removed by a method such as peeling or etching. The conductor layer 20x may be removed before performing hot press processing.

As described above, the multilayer substrate 1 shown in FIG. 1 is produced.

FIG. 7 is an example of an enlarged cross-sectional image of the multilayer substrate of Embodiment 1 of the present disclosure.

Based on the cross-sectional image of the multilayer substrate 1 shown in FIG. 7, the proportion of presence of the second resin material 11b at the interface between the first resin layer 10a and the first conductor layer 20a was confirmed to be 40% to 70%.

From the viewpoint of providing excellent adhesion between the first resin layer 10a and the first conductor layer 20a, the proportion of presence of the second resin material 11b at the interface between the first resin layer 10a and the first conductor layer 20a is preferably 50% to 70%. In addition, from the viewpoint of suppressing warpage of the multilayer substrate 1, the proportion of presence of the second resin material 11b at the interface between the first resin layer 10a and the first conductor layer 20a is preferably 40% to 60%. Accordingly, from the viewpoint of providing excellent adhesion between the first resin layer 10a and the first conductor layer 20a and suppressing warpage of the multilayer substrate 1, the proportion of presence of the second resin material 11b at the interface between the first resin layer 10a and the first conductor layer 20a is preferably 50% to 60%.

In the multilayer substrate 1, at the interface between the second resin layer 10b and the first conductor layer 20a in the first cross-section, the proportion of presence of the second resin material 11b (hereinafter also referred to as “the proportion of presence of the second resin material 11b at the interface between the second resin layer 10b and the first conductor layer 20a”) is preferably 40% to 70%. From the viewpoint of providing excellent adhesion between the second resin layer 10b and the first conductor layer 20a, the proportion of presence of the second resin material 11b at the interface between the second resin layer 10b and the first conductor layer 20a is more preferably 50% to 70%. In addition, from the viewpoint of suppressing warpage of the multilayer substrate 1, the proportion of presence of the second resin material 11b at the interface between the second resin layer 10b and the first conductor layer 20a is more preferably 40% to 60%. Accordingly, from the viewpoint of providing excellent adhesion between the second resin layer 10b and the first conductor layer 20a and suppressing warpage of the multilayer substrate 1, the proportion of presence of the second resin material 11b at the interface between the second resin layer 10b and the first conductor layer 20a is more preferably 50% to 60%.

In the multilayer substrate 1, at the interface between the first resin layer 10a and the first conductor layer 20a in the first cross-section, the average thickness of the second resin material 11b is preferably 5 μm or less. In this case, at the interface between the first resin layer 10a and the first conductor layer 20a, the thickness of the second resin material 11b that more readily undergoes dimensional changes relative to the first conductor layer 20a is small, and thus dimensional changes of the second resin material 11b are likely to be suppressed by the first resin material 11a, resulting in excellent dimensional stability of the first resin layer 10a including the first resin material 11a and the second resin material 11b.

In the multilayer substrate 1, at the interface between the first resin layer 10a and the first conductor layer 20a in the first cross-section, the average thickness of the second resin material 11b is preferably 1 μm or more.

In the multilayer substrate 1, in the first cross-section, the average aspect ratio of the second resin material 11b is preferably 3 or more. In this case, even when tensile stress is applied to the multilayer substrate 1 as a result of pulling the multilayer substrate 1, the tensile stress is less likely to concentrate at the interface between the first resin material 11a and the second resin material 11b, and thus cracks initiated at the interface between the first resin material 11a and the second resin material 11b are less likely to occur. In addition, even when bending stress is applied to the multilayer substrate 1 as a result of bending the multilayer substrate 1, the bending stress is less likely to concentrate at the interface between the first resin material 11a and the second resin material 11b, and thus cracks initiated at the interface between the first resin material 11a and the second resin material 11b are less likely to occur. The multilayer substrate 1 therefore exhibits excellent tensile resistance and excellent bending resistance.

In the multilayer substrate 1, in the first cross-section, the average aspect ratio of the second resin material 11b is preferably 50 or less.

In the multilayer substrate 1, in the first cross-section, the average inclination of the second resin material 11b relative to the surface direction (hereinafter also referred to as “the average inclination of the second resin material 11b”) is preferably 15° or less. In this case, even when tensile stress is applied to the multilayer substrate 1 as a result of pulling the multilayer substrate 1, the tensile stress is less likely to concentrate at the interface between the first resin material 11a and the second resin material 11b, and thus cracks initiated at the interface between the first resin material 11a and the second resin material 11b are less likely to occur. In addition, even when bending stress is applied to the multilayer substrate 1 as a result of bending the multilayer substrate 1, the bending stress is less likely to concentrate at the interface between the first resin material 11a and the second resin material 11b, and thus cracks initiated at the interface between the first resin material 11a and the second resin material 11b are less likely to occur. The multilayer substrate 1 therefore exhibits excellent tensile resistance and excellent bending resistance.

In the multilayer substrate 1, in the first cross-section, the average inclination of the second resin material 11b relative to the surface direction may be 0° or more.

In the multilayer substrate 1, in the first cross-section, more preferably, the average aspect ratio of the second resin material 11b is 3 or more and the average inclination of the second resin material 11b relative to the surface direction is 15° or less. Such an embodiment is referred to as the second resin material 11b having a flat shape along the surface direction. When the second resin material 11b has a flat shape along the surface direction, even when tensile stress in the surface direction is applied to the multilayer substrate 1, locations that act as initiation points for cracks are likely to be reduced at the interface between the first resin material 11a and the second resin material 11b, which have different elastic moduli (for example, Young's moduli) in the surface direction. As a result, the multilayer substrate 1 exhibits even better tensile resistance.

The average thickness, the average aspect ratio, and the average inclination of the second resin material 11b are determined as follows.

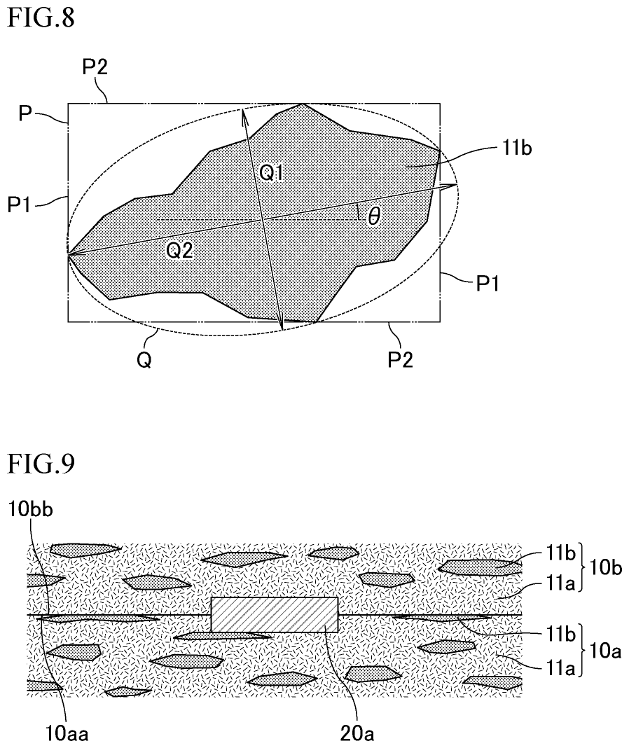

FIG. 8 is a cross-sectional view for explaining methods of determining the average thickness, the average aspect ratio, and the average inclination of the second resin material.

First, the method of determining the average thickness of the second resin material 11b will be described. In the cross-sectional image of the multilayer substrate 1 (imaging range: 100 μm (thickness direction)×200 μm (surface direction)) captured when determining the proportion of presence of the second resin material 11b at the interface between the first resin layer 10a and the first conductor layer 20a, image analysis software is used to draw, as shown in FIG. 8, a minimum-area rectangle P circumscribing a domain of the second resin material 11b. At this time, the rectangle P consists of short sides P1 extending in the thickness direction and long sides P2 extending in the surface direction. Then, the dimension of each short side P1 of the rectangle P is measured, and the dimension is defined as the thickness of the domain of the second resin material 11b. In this manner, in the cross-sectional image of the multilayer substrate 1, the thicknesses of 50 or more individual domains of the second resin material 11b present on the first main surface 10aa of the first resin layer 10a are measured, and the average value thereof is defined as the average thickness of the second resin material 11b.

Next, the method of determining the average aspect ratio of the second resin material 11b will be described. In the cross-sectional image of the multilayer substrate 1 (imaging range: 100 μm (thickness direction)×200 μm (surface direction)) captured when determining the proportion of presence of the second resin material 11b at the interface between the first resin layer 10a and the first conductor layer 20a, image analysis software is used to draw, as shown in FIG. 8, a minimum-area ellipse Q circumscribing a domain of the second resin material 11b. Then, the ratio of the dimension of a major axis Q2 to the dimension of a minor axis Q1 of the ellipse Q is determined and defined as the aspect ratio of the domain of the second resin material 11b. In this manner, in the cross-sectional image of the multilayer substrate 1, the aspect ratios of 50 or more individual domains of the second resin material 11b are measured, and the average value thereof is defined as the average aspect ratio of the second resin material 11b.

Finally, the method of determining the average inclination of the second resin material 11b will be described. In the cross-sectional image of the multilayer substrate 1 (imaging range: 100 μm (thickness direction)×200 μm (surface direction)) captured when determining the proportion of presence of the second resin material 11b at the interface between the first resin layer 10a and the first conductor layer 20a, image analysis software is used to draw, as shown in FIG. 8, a minimum-area ellipse Q circumscribing a domain of the second resin material 11b. Then, an angle θ formed by a major axis Q2 of the ellipse Q relative to the surface direction is measured, and the angle is defined as the inclination of the domain of the second resin material 11b. In this manner, in the cross-sectional image of the multilayer substrate 1, inclinations of 50 or more individual domains of the second resin material 11b are measured, and the average value thereof is defined as the average inclination of the second resin material 11b.

In the multilayer substrate 1, in a second cross-section perpendicular to the first cross-section and taken along the thickness direction, the second resin material 11b is preferably in contact with part of the main surface of the first conductor layer 20a adjacent to the first resin layer 10a. In this case, even when the second resin material 11b has a low elastic modulus (for example, Young's modulus), i.e., even when the second resin material 11b is easily deformed by an external force, the first conductor layer 20a is less likely to be displaced by an external force than in a case where the second resin material 11b is in contact with the entire main surface of the first conductor layer 20a adjacent to the first resin layer 10a.

Embodiments in which the second resin material 11b is in contact with part of the main surface of the first conductor layer 20a adjacent to the first resin layer 10a include the example shown in FIG. 2, in which the second resin material 11b is in contact with portions other than both end portions of the main surface of the first conductor layer 20a adjacent to the first resin layer 10a. However, the embodiments are not limited to the example shown in FIG. 2.

FIG. 9 is an enlarged schematic cross-sectional view of another example of the multilayer substrate of Embodiment 1 of the present disclosure, in a second cross-section.

In the example shown in FIG. 9, the second resin material 11b is in contact with one end portion of the main surface of the first conductor layer 20a adjacent to the first resin layer 10a.

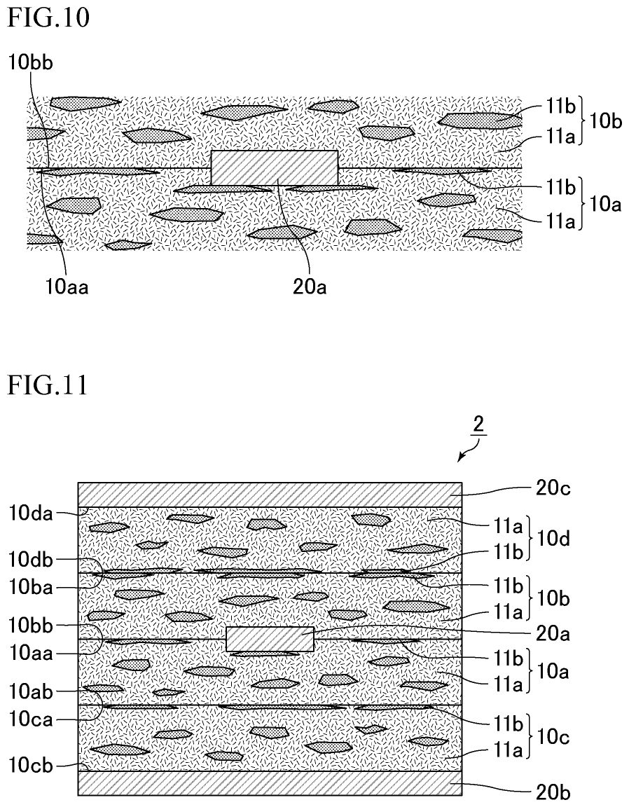

FIG. 10 is an enlarged schematic cross-sectional view of still another example of the multilayer substrate of Embodiment 1 of the present disclosure, in a second cross-section.

In the example shown in FIG. 10, the second resin material 11b is in contact with both end portions of the main surface of the first conductor layer 20a adjacent to the first resin layer 10a.

In the multilayer substrate 1, preferably, Dk1>Dk2, where Dk1 is the relative permittivity of the first resin material 11a and Dk2 is the relative permittivity of the second resin material 11b.

The relative permittivity of a resin material present in a resin layer is determined as follows. For example, when the first resin layer 10a including the first resin material 11a and the second resin material 11b is used as a sample, the first resin layer 10a is first subjected to a strong alkali treatment to extract the second resin material 11b. Thereafter, the extracted second resin material 11b is molded into a sheet shape having a thickness of 50 μm to 500 μm, thereby obtaining a resin sheet sample. The resin sheet sample is used to measure the relative permittivity of the second resin material 11b by a dielectric resonator method (mode: TE011 mode, frequency range: 12 GHz to 60 GHz). Next, the relative permittivity of the first resin layer 10a is measured by the dielectric resonator method under the same conditions as described above. Furthermore, three-dimensional structures of the first resin material 11a and the second resin material 11b in the first resin layer 10a are identified using an X-ray CT apparatus, and a volume ratio of the first resin material 11a and the second resin material 11b in the first resin layer 10a is measured using analysis software. Then, based on the relative permittivity of the first resin layer 10a and the relative permittivity of the second resin material 11b measured by the above-described method, the relative permittivity of the first resin material 11a is calculated according to the volume ratio of the first resin material 11a and the second resin material 11b in the first resin layer 10a.

In the multilayer substrate 1, preferably, Df1>Df2, where Df1 is the dielectric loss tangent of the first resin material 11a and Df2 is the dielectric loss tangent of the second resin material 11b.

The dielectric loss tangent of a resin material present in a resin layer is determined as follows. For example, when the first resin layer 10a including the first resin material 11a and the second resin material 11b is used as a sample, the first resin layer 10a is first subjected to a strong alkali treatment to extract the second resin material 11b. Thereafter, the extracted second resin material 11b is molded into a sheet shape having a thickness of 50 μm to 500 μm, thereby obtaining a resin sheet sample. The resin sheet sample is used to measure the dielectric loss tangent of the second resin material 11b by a dielectric resonator method (mode: TE011 mode, frequency range: 12 GHz to 60 GHz). Next, the dielectric loss tangent of the first resin layer 10a is measured by the dielectric resonator method under the same conditions as described above.

Furthermore, three-dimensional structures of the first resin material 11a and the second resin material 11b in the first resin layer 10a are identified using an X-ray CT apparatus, and a volume ratio of the first resin material 11a and the second resin material 11b in the first resin layer 10a is measured using analysis software. Then, based on the dielectric loss tangent of the first resin layer 10a and the dielectric loss tangent of the second resin material 11b measured by the above-described method, the dielectric loss tangent of the first resin material 11a is calculated according to the volume ratio of the first resin material 11a and the second resin material 11b in the first resin layer 10a.

In the multilayer substrate 1, the adhesion (for example, tensile elongation at break) between portions of the second resin material 11b is preferably higher than the adhesion (for example, tensile elongation at break) between portions of the first resin material 11a. In this case, the interlayer adhesion strength between the resin layers of the multilayer substrate 1 tends to be improved.

A relative magnitude of adhesion (for example, tensile elongation at break) between portions of each type of resin material present in a resin layer is determined as follows. First, in the multilayer substrate, tensile stress is applied to a resin layer by pulling the resin layer. At this time, for example, after isolating the resin layer from the multilayer substrate, a tensile test of the resin layer is performed in accordance with “JIS K 7127-1999”. Then, when tensile stress is applied to the resin layer, which resin material breaks first is determined. At this time, when breakage occurs earlier between portions of the first resin material 11a than between portions of the second resin material 11b, the adhesion between the portions of the second resin material 11b (for example, tensile elongation at break) is determined to be higher than the adhesion between the portions of the first resin material 11a (for example, tensile elongation at break).

The multilayer substrate 1 is used, for example, as a circuit board.

In the multilayer substrate 1 used as a circuit board, the first conductor layer 20a may serve as a signal line that transmits a signal, and the multilayer substrate 1 may constitute a transmission line.

When the first conductor layer 20a serves as a signal line that transmits a signal and the multilayer substrate 1 constitutes a transmission line, the condition Dk1>Dk2 as described above, together with the proportion of presence of the second resin material 11b at the interface between the first resin layer 10a and the first conductor layer 20a being 40% to 70%, allows the multilayer substrate 1 to exhibit excellent high-frequency characteristics.

When the first conductor layer 20a serves as a signal line that transmits a signal and the multilayer substrate 1 constitutes a transmission line, the condition Df1>Df2 as described above, together with the proportion of presence of the second resin material 11b at the interface between the first resin layer 10a and the first conductor layer 20a being 40% to 70%, allows the multilayer substrate 1 to exhibit excellent transmission loss characteristics.

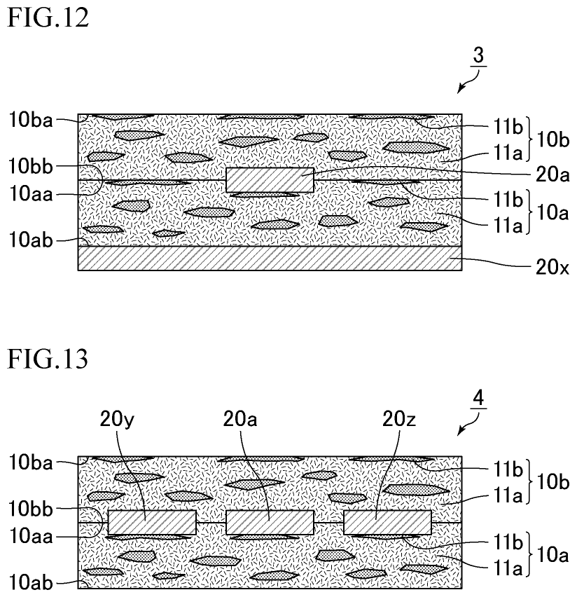

When the multilayer substrate of the present disclosure constitutes a transmission line, the multilayer substrate of the present disclosure may constitute, for example, a stripline-type transmission line, a microstrip-type transmission line, or a coplanar-type transmission line. Hereinafter, configurations of these transmission lines will be described. FIG. 11, FIG. 12, and FIG. 13 below illustrate examples of configurations of these transmission lines. For ease of understanding of the configurations of the transmission lines, FIG. 11, FIG. 12, and FIG. 13 each show a second cross-section (a cross-section of the multilayer substrate along the thickness direction of the multilayer substrate and a direction perpendicular to the extension direction of the first conductor layer), similar to FIG. 2 and the like.

### Embodiment 2

A multilayer substrate of Embodiment 2 of the present disclosure constitutes a stripline-type transmission line.

FIG. 11 is a schematic cross-sectional view of an example of a multilayer substrate of Embodiment 2 of the present disclosure, in a second cross-section.

A multilayer substrate 2 shown in FIG. 11 includes a first resin layer 10a, a second resin layer 10b, a third resin layer 10c, a fourth resin layer 10d, a first conductor layer 20a, a second conductor layer 20b, and a third conductor layer 20c.

The multilayer substrate 2 has the same configuration as the multilayer substrate 1, except that the multilayer substrate 2 includes the third resin layer 10c, the fourth resin layer 10d, the second conductor layer 20b, and the third conductor layer 20c.

The third resin layer 10c has a fifth main surface 10ca and a sixth main surface 10cb opposing each other in the thickness direction.

The fifth main surface 10ca of the third resin layer 10c faces the second main surface 10ab of the first resin layer 10a. In the example shown in FIG. 11, the fifth main surface 10ca of the third resin layer 10c is in contact with the second main surface 10ab of the first resin layer 10a.

The third resin layer 10c preferably includes the first resin material 11a and the second resin material 11b. Furthermore, in the multilayer substrate 2, in a cross-section along the thickness direction, the proportion of presence of the second resin material 11b at the fifth main surface 10ca of the third resin layer 10c is preferably 40% to 70%. In this case, in producing a laminated structure of the first resin layer 10a and the third resin layer 10c by hot press processing, similar to the mechanism described above, fluidity of the second resin material 11b present in the vicinity of the fifth main surface 10ca of the third resin layer 10c increases. This shortens the distance between the second resin material 11b in the first resin layer 10a and the second resin material 11b in the third resin layer 10c, resulting in excellent adhesion between the first resin layer 10a and the third resin layer 10c. Furthermore, similar to the mechanism described above, during the hot press processing, dimensional changes of the second resin material 11b at the fifth main surface 10ca of the third resin layer 10c are suppressed by the first resin material 11a that is less likely to undergo dimensional changes. As a result, warpage caused by a dimensional change of the third resin layer 10c is suppressed. The fifth main surface 10ca of the third resin layer 10c, i.e., the interface between the first resin layer 10a and the third resin layer 10c, is readily confirmed using a fluorescence microscope in addition to a scanning electron microscope.

In the example shown in FIG. 11, when the second cross-section is used as an example of the cross-section along the thickness direction, the proportion of presence of the second resin material 11b at the fifth main surface 10ca of the third resin layer 10c is 40% to 70%. Instead, when the first cross-section perpendicular to the second cross-section is used as an example of the cross-section along the thickness direction, the proportion of presence of the second resin material 11b at the fifth main surface 10ca of the third resin layer 10c may be 40% to 70%.

The fourth resin layer 10d has a seventh main surface 10da and an eighth main surface 10db opposing each other in the thickness direction.

The eighth main surface 10db of the fourth resin layer 10d faces the third main surface 10ba of the second resin layer 10b. In the example shown in FIG. 11, the eighth main surface 10db of the fourth resin layer 10d is in contact with the third main surface 10ba of the second resin layer 10b.

The fourth resin layer 10d preferably includes the first resin material 11a and the second resin material 11b. Furthermore, in the multilayer substrate 2, in a cross-section along the thickness direction, the proportion of presence of the second resin material 11b at the eighth main surface 10db of the fourth resin layer 10d is preferably 40% to 70%. In this case, in producing a laminated structure of the second resin layer 10b and the fourth resin layer 10d by hot press processing, similar to the mechanism described above, fluidity of the second resin material 11b present in the vicinity of the eighth main surface 10db of the fourth resin layer 10d increases. This shortens the distance between the second resin material 11b in the second resin layer 10b and the second resin material 11b in the fourth resin layer 10d, resulting in excellent adhesion between the second resin layer 10b and the fourth resin layer 10d. Furthermore, similar to the mechanism described above, during the hot press processing, dimensional changes of the second resin material 11b at the eighth main surface 10db of the fourth resin layer 10d are suppressed by the first resin material 11a that is less likely to undergo dimensional changes. As a result, warpage caused by a dimensional change of the fourth resin layer 10d is suppressed. The eighth main surface 10db of the fourth resin layer 10d, i.e., the interface between the second resin layer 10b and the fourth resin layer 10d, is readily confirmed using a fluorescence microscope in addition to a scanning electron microscope.

In the example shown in FIG. 11, when the second cross-section is used as an example of the cross-section along the thickness direction, the proportion of presence of the second resin material 11b at the eighth main surface 10db of the fourth resin layer 10d is 40% to 70%. Instead, when the first cross-section perpendicular to the second cross-section is used as an example of the cross-section along the thickness direction, the proportion of presence of the second resin material 11b at the eighth main surface 10db of the fourth resin layer 10d may be 40% to 70%.

In the multilayer substrate 2, in a cross-section along the thickness direction, the proportion of presence of the second resin material 11b at the third main surface 10ba of the second resin layer 10b is preferably 40% to 70%. In this case, in producing a laminated structure of the second resin layer 10b and the fourth resin layer 10d by hot press processing, similar to the mechanism described above, fluidity of the second resin material 11b present in the vicinity of the third main surface 10ba of the second resin layer 10b increases. This shortens the distance between the second resin material 11b in the second resin layer 10b and the second resin material 11b in the fourth resin layer 10d, resulting in excellent adhesion between the second resin layer 10b and the fourth resin layer 10d. Furthermore, similar to the mechanism described above, during the hot press processing, dimensional changes of the second resin material 11b at the third main surface 10ba of the second resin layer 10b are suppressed by the first resin material 11a that is less likely to undergo dimensional changes. As a result, warpage caused by a dimensional change of the second resin layer 10b is suppressed. The third main surface 10ba of the second resin layer 10b, i.e., the interface between the second resin layer 10b and the fourth resin layer 10d, is readily confirmed using a fluorescence microscope in addition to a scanning electron microscope.

In the example shown in FIG. 11, when the second cross-section is used as an example of the cross-section along the thickness direction, the proportion of presence of the second resin material 11b at the third main surface 10ba of the second resin layer 10b is 40% to 70%. Instead, when the first cross-section perpendicular to the second cross-section is used as an example of the cross-section along the thickness direction, the proportion of presence of the second resin material 11b at the third main surface 10ba of the second resin layer 10b may be 40% to 70%.

The first resin layer 10a, the second resin layer 10b, the third resin layer 10c, and the fourth resin layer 10d may have the same thickness, or some or all of these may have different thicknesses.

The second conductor layer 20b is in contact with the sixth main surface 10cb of the third resin layer 10c. In this manner, no other layer such as an adhesive layer is provided between the third resin layer 10c and the second conductor layer 20b.

The second conductor layer 20b may be in the form of a planar shape extending over the entire sixth main surface 10cb of the third resin layer 10c, or may be in the form of a pattern shape patterned as wiring or the like on a part of the sixth main surface 10cb of the third resin layer 10c.

The third conductor layer 20c is in contact with the seventh main surface 10da of the fourth resin layer 10d. In this manner, no other layer such as an adhesive layer is provided between the fourth resin layer 10d and the third conductor layer 20c.

The third conductor layer 20c may be in the form of a planar shape extending over the entire seventh main surface 10da of the fourth resin layer 10d, or may be in the form of a pattern shape patterned as wiring or the like on a part of the seventh main surface 10da of the fourth resin layer 10d.

The constituent materials of the first conductor layer 20a, the second conductor layer 20b, and the third conductor layer 20c may be the same as one another, may be different from one another, or may be partially different.

The first conductor layer 20a, the second conductor layer 20b, and the third conductor layer 20c may have the same thickness, or some or all of these may have different thicknesses.

The multilayer substrate 2 constitutes a stripline-type transmission line. Specifically, the multilayer substrate 2 includes the first conductor layer 20a as a signal line and includes the second conductor layer 20b and the third conductor layer 20c as ground electrodes. In such a configuration, the second conductor layer 20b and the third conductor layer 20c may be electrically connected via interlayer connection conductors (not shown) extending through the first resin layer 10a, the second resin layer 10b, the third resin layer 10c, and the fourth resin layer 10d in the thickness direction. Alternatively, the second conductor layer 20b and the third conductor layer 20c may not be electrically connected.

The multilayer substrate 2 is produced, for example, by performing the following steps after production of the multilayer substrate 1. First, after the multilayer substrate 1 is produced, a conductor layer-attached resin sheet in which the second conductor layer 20b is adjacent to one main surface (the main surface later serving as the sixth main surface 10cb) of a resin sheet (the resin sheet later serving as the third resin layer 10c) is stacked such that the other main surface (the main surface later serving as the fifth main surface 10ca) is adjacent to the second main surface 10ab of the first resin layer 10a. Furthermore, a conductor layer-attached resin sheet in which the third conductor layer 20c is adjacent to one main surface (the main surface later serving as the seventh main surface 10da) of a resin sheet (the resin sheet later serving as the fourth resin layer 10d) is stacked such that the other main surface (the main surface later serving as the eighth main surface 10db) is adjacent to the third main surface 10ba of the second resin layer 10b. Then, hot press processing is performed on the obtained stack by pressing the stack in the thickness direction while heating.

The temperature during the hot press processing is preferably equal to or higher than the melting point of the second resin material 11b and equal to or lower than the melting point of the first resin material 11a (i.e., Tm2 or higher and Tm1 or lower), and more preferably equal to or higher than the melting point of the second resin material 11b and equal to or lower than a temperature that is 10 °C lower than the melting point of the first resin material 11a (i.e., Tm2 or higher and (Tm1−10) or lower). In this case, a temperature increase rate during the hot press processing is preferably 5 °C/min or higher, more preferably 5 °C/min or higher and 50 °C/min or lower. When hot press processing is performed, for example, under the temperature conditions described above, as shown in FIG. 11, the second resin material 11b can be caused to be present at each of the third main surface 10ba of the second resin layer 10b, the fifth main surface 10ca of the third resin layer 10c, and the eighth main surface 10db of the fourth resin layer 10d at a proportion of presence of 40% to 70% while maintaining a flat shape along the surface direction.

### Embodiment 3

A multilayer substrate of Embodiment 3 of the present disclosure constitutes a microstrip-type transmission line.

FIG. 12 is a schematic cross-sectional view of an example of a multilayer substrate of Embodiment 3 of the present disclosure, in a second cross-section.

A multilayer substrate 3 shown in FIG. 12 includes a first resin layer 10a, a second resin layer 10b, a first conductor layer 20a, and a conductor layer 20x.

The multilayer substrate 3 has the same configuration as the multilayer substrate 1, except that the multilayer substrate 3 includes the conductor layer 20x.

The conductor layer 20x is in contact with the second main surface 10ab of the first resin layer 10a. In this manner, no other layer such as an adhesive layer is provided between the first resin layer 10a and the conductor layer 20x.

The constituent materials of the first conductor layer 20a and the conductor layer 20x may be the same as each other or may be different from each other.

The first conductor layer 20a and the conductor layer 20x may have the same thickness or may have different thicknesses.

The multilayer substrate 3 constitutes a microstrip-type transmission line. Specifically, the multilayer substrate 3 includes the first conductor layer 20a as a signal line and includes the conductor layer 20x as a ground electrode.

The multilayer substrate 3 is produced in the same manner as the multilayer substrate 1, except that the conductor layer 20x is not removed, for example.

### Embodiment 4

A multilayer substrate of Embodiment 4 of the present disclosure constitutes a coplanar-type transmission line.

FIG. 13 is a schematic cross-sectional view of an example of a multilayer substrate of Embodiment 4 of the present disclosure, in a second cross-section.

A multilayer substrate 4 shown in FIG. 13 includes a first resin layer 10a, a second resin layer 10b, a first conductor layer 20a, a conductor layer 20y, and a conductor layer 20z.

The multilayer substrate 4 has the same configuration as the multilayer substrate 1, except that the multilayer substrate 4 includes the conductor layer 20y and the conductor layer 20z.

The conductor layer 20y is located between the first resin layer 10a and the second resin layer 10b and is in contact with the first main surface 10aa of the first resin layer 10a and the fourth main surface 10bb of the second resin layer 10b. In this manner, no other layer such as an adhesive layer is provided between the first resin layer 10a and the conductor layer 20y and between the second resin layer 10b and the conductor layer 20y.

The conductor layer 20y preferably extends across the interface between the first resin layer 10a and the second resin layer 10b. Accordingly, the interface between the first resin layer 10a and the conductor layer 20y and the interface between the second resin layer 10b and the conductor layer 20y are shifted in the thickness direction relative to the interface between the first resin layer 10a and the second resin layer 10b, thereby suppressing peeling at the interface between the first resin layer 10a and the conductor layer 20y and peeling at the interface between the second resin layer 10b and the conductor layer 20y.

The conductor layer 20z is located between the first resin layer 10a and the second resin layer 10b and is in contact with the first main surface 10aa of the first resin layer 10a and the fourth main surface 10bb of the second resin layer 10b. In this manner, no other layer such as an adhesive layer is provided between the first resin layer 10a and the conductor layer 20z and between the second resin layer 10b and the conductor layer 20z.

The conductor layer 20z preferably extends across the interface between the first resin layer 10a and the second resin layer 10b. Accordingly, the interface between the first resin layer 10a and the conductor layer 20z and the interface between the second resin layer 10b and the conductor layer 20z are shifted in the thickness direction relative to the interface between the first resin layer 10a and the second resin layer 10b, thereby suppressing peeling at the interface between the first resin layer 10a and the conductor layer 20z and peeling at the interface between the second resin layer 10b and the conductor layer 20z.

The constituent materials of the first conductor layer 20a, the conductor layer 20y, and the conductor layer 20z may be the same as one another, may be different from one another, or may be partially different.

The first conductor layer 20a, the conductor layer 20y, and the conductor layer 20z may have the same thickness, or some or all of these may have different thicknesses.

The multilayer substrate 4 constitutes a coplanar-type transmission line. Specifically, the multilayer substrate 4 includes the first conductor layer 20a as a signal line and includes the conductor layer 20y and the conductor layer 20z as ground electrodes. In such a configuration, the conductor layer 20y and the conductor layer 20z may be integrated by being connected in the surface direction.

The multilayer substrate 4 is produced, for example, in the same manner as the multilayer substrate 1, except that, in producing a conductor layer-attached second resin sheet 210b (see FIG. 5), the conductor layer 20y and the conductor layer 20z as well as the first conductor layer 20a are provided so as to be adjacent to the fourth main surface 110bb of the second resin sheet 110b.

### Embodiment 5

A multilayer substrate of Embodiment 5 of the present disclosure has bent portions.

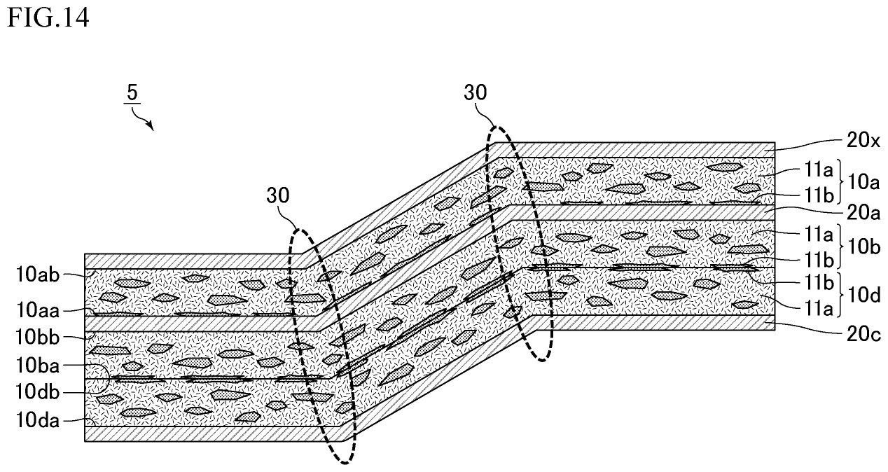

FIG. 14 is a schematic cross-sectional view of an example of a multilayer substrate of Embodiment 5 of the present disclosure, in a first cross-section.

A multilayer substrate 5 shown in FIG. 14 includes a first resin layer 10a, a second resin layer 10b, a fourth resin layer 10d, a first conductor layer 20a, a third conductor layer 20c, and a conductor layer 20x.

The multilayer substrate 5 has the same configuration as the multilayer substrate 2, except that the multilayer substrate 5 includes the conductor layer 20x instead of the third resin layer 10c and the second conductor layer 20b.

The conductor layer 20x is in contact with the second main surface 10ab of the first resin layer 10a. In this manner, no other layer such as an adhesive layer is provided between the first resin layer 10a and the conductor layer 20x.

The constituent materials of the first conductor layer 20a, the third conductor layer 20c, and the conductor layer 20x may be the same as one another, may be different from one another, or may be partially different.

The first conductor layer 20a, the third conductor layer 20c, and the conductor layer 20x may have the same thickness, or some or all of these may have different thicknesses.

The multilayer substrate 5 has one or more bent portions 30. In the example shown in FIG. 14, the multilayer substrate 5 has two bent portions 30. The multilayer substrate 5 may have one bent portion 30 or may have three or more bent portions 30.

The position of each bent portion 30 is not limited.

Since the multilayer substrate 5 has the bent portions 30, even when tensile stress is applied to the multilayer substrate 5 as a result of pulling the multilayer substrate 5, locations at which tensile stress concentrates are reduced, and thus the multilayer substrate 5 is less prone to break. In addition, even when bending stress is applied to the multilayer substrate 5 as a result of bending the multilayer substrate 5, locations at which bending stress concentrates are reduced, and thus the multilayer substrate 5 is less prone to break. The multilayer substrate 5 therefore exhibits excellent tensile resistance and excellent bending resistance.

Furthermore, since the multilayer substrate 5 has the bent portions 30, the multilayer substrate 5, when used as a circuit board, can constitute a transmission line in a bent state.

### Embodiment 6

A multilayer substrate of Embodiment 6 of the present disclosure has a recess in addition to bent portions.

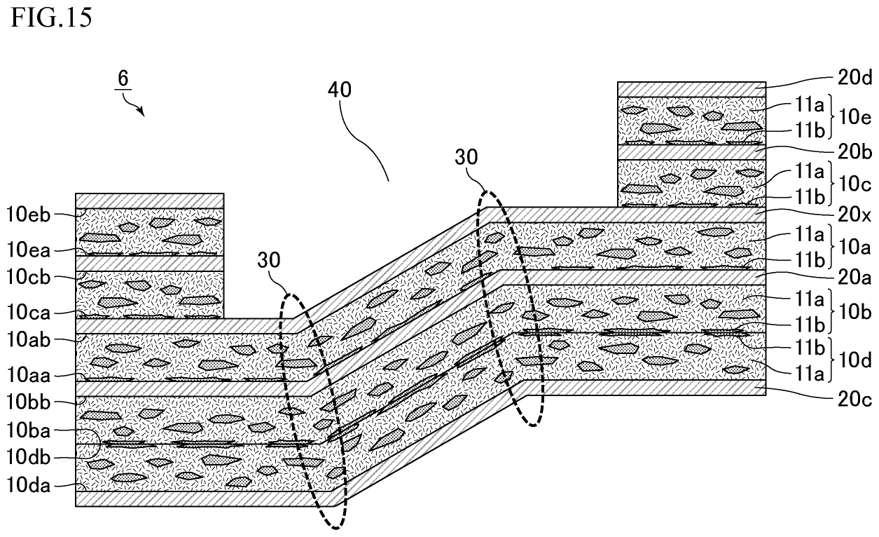

FIG. 15 is a schematic cross-sectional view of an example of a multilayer substrate of Embodiment 6 of the present disclosure, in a first cross-section.

A multilayer substrate 6 shown in FIG. 15 includes a first resin layer 10a, a second resin layer 10b, a third resin layer 10c, a fourth resin layer 10d, a fifth resin layer 10e, a first conductor layer 20a, a second conductor layer 20b, a third conductor layer 20c, a fourth conductor layer 20d, and a conductor layer 20x.

The multilayer substrate 6 has the same configuration as the multilayer substrate 5, except that the multilayer substrate 6 includes the third resin layer 10c, the fifth resin layer 10e, the second conductor layer 20b, and the fourth conductor layer 20d.

The fifth main surface 10ca of the third resin layer 10c faces the second main surface 10ab of the first resin layer 10a with the conductor layer 20x interposed therebetween.

The fifth resin layer 10e has a ninth main surface 10ea and a tenth main surface 10eb opposing each other in the thickness direction.

The ninth main surface 10ea of the fifth resin layer 10e faces the sixth main surface 10cb of the third resin layer 10c with the second conductor layer 20b interposed therebetween.

The fifth resin layer 10e preferably includes the first resin material 11a and the second resin material 11b. Furthermore, in the multilayer substrate 6, at the interface between the fifth resin layer 10e and the second conductor layer 20b in the first cross-section, the proportion of presence of the second resin material 11b is preferably 40% to 70%. In this case, similar to the mechanism described above, the adhesion between the fifth resin layer 10e and the second conductor layer 20b becomes excellent, and furthermore, warpage caused by a difference in dimensional change between the fifth resin layer 10e and the second conductor layer 20b is suppressed.

The first resin layer 10a, the second resin layer 10b, the third resin layer 10c, the fourth resin layer 10d, and the fifth resin layer 10e may have the same thickness, or some or all of these may have different thicknesses.

The second conductor layer 20b is located between the third resin layer 10c and the fifth resin layer 10e and is in contact with the sixth main surface 10cb of the third resin layer 10c and the ninth main surface 10ea of the fifth resin layer 10e.

The fourth conductor layer 20d is in contact with the tenth main surface 10eb of the fifth resin layer 10e. In this manner, no other layer such as an adhesive layer is provided between the fifth resin layer 10e and the fourth conductor layer 20d.

The constituent materials of the first conductor layer 20a, the second conductor layer 20b, the third conductor layer 20c, the fourth conductor layer 20d, and the conductor layer 20x may be the same as one another, may be different from one another, or may be partially different.

The first conductor layer 20a, the second conductor layer 20b, the third conductor layer 20c, the fourth conductor layer 20d, and the conductor layer 20x may have the same thickness, or some or all of these may have different thicknesses.

The multilayer substrate 6 has one or more bent portions 30. In the example shown in FIG. 15, the multilayer substrate 6 has two bent portions 30.

The multilayer substrate 6 having the bent portions 30, similar to the multilayer substrate 5, exhibits excellent tensile resistance and excellent bending resistance.

Furthermore, the multilayer substrate 6 having the bent portions 30, when used as a circuit board, can constitute a transmission line in a bent state.

The multilayer substrate 6 has a recess 40 as well as the bent portions 30. In the example shown in FIG. 15, the recess 40 reaches the conductor layer 20x while extending through the fourth conductor layer 20d, the fifth resin layer 10e, the second conductor layer 20b, and the third resin layer 10c in the thickness direction.

The position of the recess 40 is not limited.

The size (width, height, and the like) of the recess 40 is not limited.

The recess 40 can be used as a space for mounting electronic components and the like on the multilayer substrate 6. When electronic components and the like are mounted in the recess 40 of the multilayer substrate 6, the overall thickness of the assembly in which the electronic components and the like are mounted on the multilayer substrate 6 can be suppressed.

The multilayer substrate of the present disclosure is not limited to the above embodiments, and various applications and modifications can be made for the configuration, production conditions, and the like of the multilayer substrate within the scope of the present disclosure.

In the multilayer substrate of the present disclosure, the number of resin layers is not limited as long as the multilayer substrate includes two or more layers including the first resin layer and the second resin layer.

In the multilayer substrate of the present disclosure, the number of conductor layers is not limited as long as the multilayer substrate includes one or more layers including the first conductor layer.

### EXAMPLES

Examples that more specifically disclose the multilayer substrate of the present disclosure are described below. The present disclosure is not limited to these examples.

### Examples 1 to 10

Multilayer substrates of Examples 1 to 10 were produced by the method of producing the multilayer substrate of Embodiment 1. Production conditions were as shown in Tables 1 and 2.

### Comparative Example 1

A multilayer substrate of Comparative Example 1 was produced by the same production method as in Examples 1 to 10, except that hot press processing in <Step of producing conductor layer-attached resin sheet> and <Step of stacking conductor layer-attached resin sheets> was performed at a temperature outside the range of Tm2 or higher and Tm1 or lower, specifically at a temperature higher than Tm1. Other production conditions were as shown in Tables 1 and 2.

### Comparative Example 2

A multilayer substrate of Comparative Example 2 was produced by the same production method as in Examples 1 to 10, except that a first resin material and a second resin material satisfying Tm1<Tm2 were used. Other production conditions were as shown in Tables 1 and 2.

“Adhesive PFA” shown in Tables 1 and 2 is “Fluon+ (registered trademark) EA-2000” produced by AGC Inc.

The “blending amount” of the second resin material shown in Tables 1 and 2 is an amount of the second resin material blended into the first resin material in preparation of the resin composition in <Step of producing conductor layer-attached resin sheet>.

The conditions of “hot press processing” shown in Tables 1 and 2 are common between <Step of producing conductor layer-attached resin sheet> and <Step of stacking conductor layer-attached resin sheets>.

### [Evaluation]

The following evaluations were conducted for the multilayer substrates of Example 1 to 10 and Comparative Examples 1 and 2. The evaluation results are shown in Tables 1 and 2.

### <Proportion of Presence of Second Resin Material>

The proportion of presence of the second resin material at the first main surface of the first resin layer (described as “Proportion of presence of second resin material” in Tables 1 and 2) was determined by the method described above (see FIG. 3).

### <Coefficient of Thermal Expansion of First Resin Layer in Surface Direction>

First, the first resin layer was isolated from the multilayer substrate by removing the first conductor layer and the second resin layer by a method such as peeling or etching. Next, a sample having a length of 20 mm and a width of 4 mm was cut out from the first resin layer and set in the probe of a thermomechanical analyzer produced by Seiko Instruments Inc. with a distance between chucks of 10 mm. Thereafter, while a load of 5 g was applied to the sample, the sample was heated to 170 °C at a heating rate of 40 °C/min and then cooled to 30 °C at a cooling rate of 10 °C/min. Then, in the cooling process, the amount of change in the distance between chucks in a temperature range from 100 °C to 50 °C was measured to determine the coefficient of thermal expansion of the first resin layer in the surface direction (described as “Coefficient of thermal expansion of first resin layer” in Tables 1 and 2).

### <Peel Strength>

As an index of adhesion between the first resin layer and the first conductor layer, the peel strength (at peeling in a 90° direction) between the first resin layer and the first conductor layer was measured in accordance with Section 5.7 of “JIS C 6481-1996”, except that the first conductor layer was peeled from the first resin layer.

### <Amount of Warpage>

The amount of warpage of the multilayer substrate was measured in accordance with Section 5.22 of “JIS C 6481-1996”. At this time, the sample was set to have a length of 120 mm and a width of 120 mm.

TABLE 1

| | | | | Example 1 | Example 2 | Example 3 | Example 4 | Example 5 | Example 6 |
|---|---|---|---|---|---|---|---|---|---|
| Production | First resin | Type | — | LCP | LCP | LCP | LCP | LCP | LCP |
| conditions | material | Tm1 | °C | 325 | 325 | 325 | 325 | 325 | 325 |
| | | CTE1 | ppm/°C | 12 | 12 | 12 | 12 | 12 | 12 |
| | Second | Type | — | Adhesive | Adhesive | Adhesive | Adhesive | TPI | PPS |
| | resin | | | PFA | PFA | PFA | PFA | | |
| | material | Tm2 | °C | 300 | 300 | 300 | 300 | 300 | 275 |
| | | CTE2 | ppm/°C | 130 | 130 | 130 | 130 | 55 | 49 |
| | | Blending | vol % | 30 | 40 | 40 | 40 | 45 | 45 |
| | | amount | | | | | | | |
| | First | Type | — | Copper | Copper | Copper | Copper | Copper | Copper |
| | conductor | CTE3 | ppm/°C | 16 | 16 | 16 | 16 | 16 | 16 |
| | layer | | | | | | | | |
| | Hot press | Temperature | °C | 310 | 310 | 315 | 320 | 310 | 310 |
| | processing | Time | h | 1 | 1 | 1 | 1 | 1 | 1 |

| | | | | | | | | |
|---|---|---|---|---|---|---|---|---|
| Evaluation | Proportion of presence of | % | 40 | 50 | 60 | 70 | 60 | 60 |
| results | second resin material | | | | | | | |
| | Coefficient of thermal | ppm/°C | 18.3 | 20.6 | 23.2 | 25.0 | 19.3 | 17.2 |
| | expansion of first resin | | | | | | | |
| | layer | | | | | | | |
| | Peel strength | N/mm | 0.15 | 0.2 | 0.2 | 0.2 | 0.2 | 0.2 |
| | Amount of warpage | mm | 0 | 3 | 5 | 7 | 1 | −1 |

TABLE 2

| | | | | | | | | Comparative | Comparative |
|---|---|---|---|---|---|---|---|---|---|
| | | | | Example 7 | Example 8 | Example 9 | Example 10 | Example 1 | Example 2 |
| Production | First resin | Type | — | LCP | LCP | LCP | LCP | LCP | LCP |
| conditions | material | Tm1 | °C | 325 | 325 | 325 | 325 | 325 | 325 |
| | | CTE1 | ppm/°C | 12 | 12 | 12 | 12 | 12 | 12 |
| | Second | Type | — | PPE | XLPE | PNB | PMP | Adhesive | PEEK |
| | resin | | | | | | | PFA | |
| | material | Tm2 | °C | 214(Tg) | 123 | 170(Tg) | 232 | 300 | 334 |
| | | CTE2 | ppm/°C | 56 | 120 | 58 | 117 | 130 | 50 |
| | | Blending | vol % | 45 | 40 | 45 | 40 | 40 | 40 |
| | | amount | | | | | | | |
| | First | Type | — | Copper | Copper | Copper | Copper | Copper | Copper |
| | conductor | CTE3 | ppm/°C | 16 | 16 | 16 | 16 | 16 | 16 |
| | layer | | | | | | | | |
| | Hot press | Temperature | °C | 310 | 310 | 310 | 310 | 350 | 310 |
| | processing | Time | h | 1 | 1 | 1 | 1 | 1 | 1 |

| | | | | | | | | |
|---|---|---|---|---|---|---|---|---|
| Evaluation | Proportion of presence of | % | 60 | 50 | 60 | 60 | 80 | 50 |
| results | second resin material | | | | | | | |
| | Coefficient of thermal | ppm/°C | 23.6 | 21.0 | 23.6 | 23.1 | 35.3 | 13.8 |
| | expansion of first resin | | | | | | | |
| | layer | | | | | | | |
| | Peel strength | N/mm | 0.2 | 0.2 | 0.2 | 0.2 | 0.2 | 0.01 |
| | Amount of warpage | mm | 6 | 3 | 6 | 3 | 17 | −4 |

As shown in Tables 1 and 2, the multilayer substrates of Examples 1 to 10, satisfying all of Tm1>Tm2, |CTE3−CTE2|>|CTE3−CTE1|, and the proportion of presence of the second resin material at the interface between the first resin layer and the first conductor layer being 40% to 70%, had high peel strength between the first resin layer and the first conductor layer, thus exhibiting excellent adhesion therebetween. Furthermore, the multilayer substrates of Examples 1 to 10 had a coefficient of thermal expansion of the first resin layer in the surface direction close to the coefficient of thermal expansion of the first conductor layer in the surface direction (CTE3), thus suppressing warpage caused by a difference in dimensional change between the first resin layer and the first conductor layer.

Among the multilayer substrates of Examples 1 to 10, the multilayer substrates of Examples 2 to 10, in which the proportion of presence of the second resin material at the interface between the first resin layer and the first conductor layer was 50% to 70%, exhibited better adhesion between the first resin layer and the first conductor layer than the multilayer substrate of Example 1, in which the proportion of presence of the second resin material at the interface between the first resin layer and the first conductor layer was 40%.

Among the multilayer substrates of Examples 1 to 10, the multilayer substrates of Examples 1 to 3 and 5 to 10, in which the proportion of presence of the second resin material at the interface between the first resin layer and the first conductor layer was 40% to 60%, exhibited less warpage than the multilayer substrate of Example 4, in which the proportion of presence of the second resin material at the interface between the first resin layer and the first conductor layer was 70%.

The multilayer substrate of Comparative Example 1, in which the proportion of presence of the second resin material at the interface between the first resin layer and the first conductor layer was greater than 70%, exhibited greater warpage than the multilayer substrates of Examples 1 to 10.

The multilayer substrate of Comparative Example 2 including the first resin material and the second resin material having a relationship of Tm1<Tm2 exhibited poorer adhesion between the first resin layer and the first conductor layer than the multilayer substrates of Examples 1 to 10.

### REFERENCE SIGNS LIST

1, 2, 3, 4, 5, 6 multilayer substrate
10a first resin layer
10aa, 110aa first main surface
10ab, 110ab second main surface
10b second resin layer
10ba, 110ba third main surface
10bb, 110bb fourth main surface
10c third resin layer
10ca fifth main surface
10cb sixth main surface
10d fourth resin layer
10da seventh main surface
10db eighth main surface
10e fifth resin layer
10ea ninth main surface
10eb tenth main surface
11a first resin material
11b second resin material
20a first conductor layer
20b second conductor layer
20c third conductor layer
20d fourth conductor layer
20x, 20y, 20z conductor layer
30 bent portion
40 recess
110a first resin sheet
110b second resin sheet
210a conductor layer-attached first resin sheet
210b conductor layer-attached second resin sheet
K dimension in thickness direction of imaging range
L dimension in surface direction of imaging range
L1, L2, L3, L4, L5, L6 dimension in surface direction of portion of second resin material in contact with interface between first resin layer and first conductor layer
P rectangle
P1 short side
P2 long side
Q ellipse
Q1 minor axis
Q2 major axis
θ angle

1. A multilayer substrate comprising:
a first resin layer having a first main surface and a second main surface opposing each other in a thickness direction;
a second resin layer having a third main surface and a fourth main surface opposing each other in the thickness direction, the fourth main surface facing the first main surface; and
a first conductor layer between the first resin layer and the second resin layer and in contact with the first main surface and the fourth main surface,
wherein the first resin layer and the second resin layer each include a first resin material comprising a first thermoplastic resin and a second resin material comprising a second thermoplastic resin and dispersed in the first resin material,
wherein Tm1>Tm2, where Tm1 is a melting point of the first resin material, and Tm2 is a melting point of the second resin material,
wherein, in a surface direction perpendicular to the thickness direction, |CTE3−CTE2|>|CTE3−CTE1|, where CTE1 is a coefficient of thermal expansion of the first resin material, CTE2 is a coefficient of thermal expansion of the second resin material, and CTE3 is a coefficient of thermal expansion of the first conductor layer, and
wherein, at an interface between the first resin layer and the first conductor layer in at least one first cross-section taken along the thickness direction, a proportion of presence of the second resin material is 40% to 70%.

2. The multilayer substrate according to claim 1, wherein, at the interface between the first resin layer and the first conductor layer in the at least one first cross-section, an average thickness of the second resin material is 5 μm or less.

3. The multilayer substrate according to claim 1, wherein, in the at least one first cross-section, an average aspect ratio of the second resin material is 3 or more.

4. The multilayer substrate according to claim 1, wherein, in the at least one first cross-section, an average inclination of the second resin material relative to the surface direction is 15° or less.

5. The multilayer substrate according to claim 1, wherein, in at least one second cross-section perpendicular to the at least one first cross-section and taken along the thickness direction, the second resin material is in contact with part of a main surface of the first conductor layer adjacent to the first resin layer.

6. The multilayer substrate according to claim 1, wherein the first conductor layer is configured as a signal line that transmits a signal, and the multilayer substrate is configured as a transmission line.

7. The multilayer substrate according to claim 1, further comprising a third resin layer having a fifth main surface and a sixth main surface opposing each other in the thickness direction, the fifth main surface facing the second main surface.

8. The multilayer substrate according to claim 7,
wherein the third resin layer includes the first resin material and the second resin material, and
at the fifth main surface in a cross-section taken along the thickness direction, a proportion of presence of the second resin material is 40% to 70%.

9. The multilayer substrate according to claim 7, further comprising a second conductor layer in contact with the sixth main surface.

10. The multilayer substrate according to claim 7, further comprising a fourth resin layer having a seventh main surface and an eighth main surface opposing each other in the thickness direction, the eighth main surface facing the third main surface.

11. The multilayer substrate according to claim 10,
wherein the fourth resin layer includes the first resin material and the second resin material, and
at the eighth main surface in a cross-section taken along the thickness direction, a proportion of presence of the second resin material is 40% to 70%.

12. The multilayer substrate according to claim 10, further comprising a third conductor layer in contact with the seventh main surface.

13. The multilayer substrate according to claim 1, further comprising:
a third resin layer having a fifth main surface and a sixth main surface opposing each other in the thickness direction, the fifth main surface facing the second main surface;
a fourth resin layer having a seventh main surface and an eighth main surface opposing each other in the thickness direction, the eighth main surface facing the third main surface;
a second conductor layer in contact with the sixth main surface; and
a third conductor layer in contact with the seventh main surface,
wherein the third resin layer includes the first resin material and the second resin material, and at the fifth main surface in a cross-section taken along the thickness direction, a proportion of presence of the second resin material is 40% to 70%, and
wherein the fourth resin layer includes the first resin material and the second resin material, and at the eighth main surface in a cross-section taken along the thickness direction, a proportion of presence of the second resin material is 40% to 70%.

14. The multilayer substrate according to claim 1, wherein CTE1<CTE2.

15. The multilayer substrate according to claim 14, wherein a difference between CTE1 and CTE2 is 20 ppm/°C to 120 ppm/°C.

16. The multilayer substrate according to claim 1, wherein Dk1>Dk2, where Dk1 is a relative permittivity of the first resin material, and Dk2 is a relative permittivity of the second resin material.

17. The multilayer substrate according to claim 1, wherein Df1>Df2, where Df1 is a dielectric loss tangent of the first resin material, and Df2 is a dielectric loss tangent of the second resin material.

18. The multilayer substrate according to claim 1, wherein the first thermoplastic resin comprises a liquid crystal polymer.

19. The multilayer substrate according to claim 18, wherein the second thermoplastic resin comprises perfluoroalkoxyalkane, thermoplastic polyimide, polyphenylene sulfide, polyether ether ketone, polyphenylene ether, polymethyl pentene, crosslinked polyethylene, or polynorbornene.

20. The multilayer substrate according to claim 1, wherein the second thermoplastic resin comprises perfluoroalkoxyalkane, thermoplastic polyimide, polyphenylene sulfide, polyether ether ketone, polyphenylene ether, polymethyl pentene, crosslinked polyethylene, or polynorbornene.
